(19) United States
(12) Patent Application Publication
(10) Pub. No.: US 2008/0315213 A1
(43) Pub. Date: Dec. 25, 2008

(54) Process for Producing an Electroluminescent P-N Junction Made of a Semiconductor Material by Molecular Bonding

(75) Inventor: Pierre Noe, Coublevie (FR)

Correspondence Address: OBLON, SPIVAK, MCCLELLAND MAIER & NEUSTADT, P.C., 1940 DUKE STREET, ALEXANDRIA, VA, 22314, US

(73) Assignee: Commissariat A L'energie Atomique, Paris (FR)

(21) Appl. No.: 12/158,050

(22) PCT Filed: Dec. 26, 2006
(86) PCT No.: PCT/EP06/70209

§ 371 Date: Jun. 19, 2008

(30) Foreign Application Priority Data
Dec. 28, 2005 (FR) 0554117

(51) Int. Cl. H01L 29/26; H01L 21/00

(52) U.S. Cl. 257/79; 438/38; 257/E33.001

(57) ABSTRACT

A method for making an electroluminescent PN junction includes molecular bonding a face in a crystalline semiconducting material doped with a first type of a first element with a face in a crystalline semiconducting material doped with a second type opposite to the first type, of a second element, at a bonding interface. The semiconducting material has an indirect forbidden band. The crystalline lattices shown by the faces are shifted in rotation by a predetermined angle so as to at least cause formation of a network of screw type dislocations at the bonding interface.

### TECHNICAL FIELD

The present invention relates to a method for making an electroluminescent PN junction in a semiconducting material with an indirect forbidden band by molecular bonding.

### STATE OF THE PRIOR ART

Silicon is the most used semiconducting material in the microelectronics industry. From the point of view of manufacturing cost and of technological maturity, this would be the most advantageous substrate for making optoelectronic circuits. Unfortunately, bulk single-crystal silicon is a not very efficient light emitter because of its indirect forbidden band. As a reminder, the forbidden band or gap of a material corresponds to the energy difference between its conduction band and its valence band. The electrons in the conduction band and the holes in the valence band have energy which depends on their wave vector. The maximum of the valence band and the minimum of the conduction band are located in this way. When the minimum of the conduction band has the same wave vector as the maximum of the valence band, the forbidden band is said to be direct, and it is said to be indirect in the opposite case. Therefore, semiconductors with a direct forbidden band are generally better suited than the other ones for optoelectronic applications. Indeed, the light-emitting devices emit at a wavelength which is determined by their forbidden band width.

As a conclusion, silicon and the other semiconducting materials with an indirect forbidden band such as germanium may be used with difficulty as an integrated light source. For silicon, light is emitted at a single wavelength of 1,150 nanometres with is located in the infrared portion of the electromagnetic light spectrum. Bulk silicon further has a photoluminescence efficiency or internal quantum yield of less than 0.01%.

Different approaches have been contemplated in order to improve the luminescence properties of silicon, and/or for causing it to emit in the visible portion of the electromagnetic light spectrum, such as silicon nanocrystals, Si/SiO₂ superlattices, porous silicon, silicon doped with erbium. Porous silicon has a forbidden band structure slightly different from that of bulk silicon because of quantum confinement present in such structures.

The most efficient light-emitting devices, emitting at the wavelength which corresponds to the forbidden band width of silicon were observed on dislocation loop devices as described in document [1], the references of which are found at the end of the description. These are light-emitting diodes made by implanting a P type dopant such as boron in a substrate of type N. This implantation induces dislocations in the silicon crystal and by annealing at about 1,000° C. a network of dislocation loops may be formed. These dislocation loops generate a localized field of stresses which locally changes the electronic band structure of the crystal and thus allows spatial confinement of the electronic carriers. It is this spatial confinement which allows electroluminescence to be obtained at the wavelength which corresponds to the width of the forbidden band of silicon, at room temperature, with an internal quantum yield close to 0.1%. However, the method for obtaining dislocation loops by ion implantation has limits because of the minimum size of the dislocation loops on the one hand, their diameter being comprised between about 80 and 100 nanometres and because of their density on the other hand, their spacing being of at least 20 nanometres. These dimensions limit integration of the components made with materials having these dislocations.

In other techniques, the dislocation loops are obtained by plastically deforming the crystal before doping, for example by compression. Document [2], the references of which are found at the end of the description, illustrates this embodiment. These dislocations, by forming <<quantum wells>> in the crystal or by behaving as traps e.g. for oxide precipitates, as this will be seen later on, allow light to be emitted at wavelengths above that corresponding to the forbidden band width of bulk silicon and in particular around 1,150 to 1,600 nanometres. But the method for making diodes with dislocations obtained by plastically deforming the crystal is not easily compatible with standard ultra-large-scale integration technology (ULSI) used in microelectronics. With such a technology, chips having more than a million of components may be obtained. These diodes obtained by plastic deformation have shapes and dislocation densities which may not be easily controlled. It is then difficult to contemplate their subsequent integration into microelectronic and/or photonic devices requiring very well controlled and reproducible flatnesses and interface conditions.

The dislocations also act as traps for silicon oxide precipitates, the latter being formed during diffusion of residual oxygen from the crystal during a high temperature annealing step. It was observed that with these precipitates light may be emitted at wavelengths above that corresponding to the gap of silicon.

Further, PN junction diodes were made by molecular bonding of two single crystal silicon wafers having a network of dislocations due to a resulting tilt angle between the vertical axes of the crystal lattices of both wafers. This angle is also known under the name of flexure angle or <<tilt>> or <<miscut>> angle. This flexure angle is practically unavoidable when both wafers are assembled together. Electroluminescence between 1,400 and 1,600 nanometres was observed in a cryostat at low temperatures of the order of 77° K. But the temperature is still much too low for current use. Further, it is very difficult to control the pitch of the dislocations and therefore their density so that it is not possible to optimize the efficiency of the PN junction and to make reproducible PN junctions.

### DISCUSSION OF THE INVENTION

The object of the present invention is to propose a method for making an electroluminescent PN junction in a semiconducting material with an indirect forbidden band which does not have the above limitations and difficulties.

In particular, an object of the present invention is to improve the efficiency and the reproducibility for making such an electroluminescent PN junction.

Another object of the invention is to make such a PN junction capable of emitting at a wavelength corresponding to the forbidden band width of the material which makes it up, but also at one or several other wavelengths.

Still another object of the invention is to make such a PN junction capable of emitting at room temperature.

A further object of the invention is to propose a method for making such a PN junction compatible with technologies of microelectronics.

In order to achieve these objects, the invention more specifically relates to a method for making an electroluminescent PN junction consisting in molecular bonding of a face in a crystalline semiconducting material doped with a first type of a first element with a face in a crystalline semiconducting material doped with a second type opposite to the first type, of a second element. The semiconducting material of the elements has an indirect forbidden band. Bonding is carried out by rotationally shifting by a predetermined angle the crystal lattices shown by said faces, so as to at least cause the formation of a dislocation network of the screw type at the bonding interface.

The sought objects may be achieved by forming the network of screw type dislocations, by means of molecular bonding.

The method may include a subsequent step for thermal annealing under a neutral or <<passivating>> atmosphere. By neutral atmosphere, is meant an inert atmosphere towards the material to be bonded, such as for example a vacuum, a nitrogen or argon atmosphere. By <<passivating>> atmosphere, is meant an atmosphere of any gas which does not prevent molecular bonding and formation of the network of dislocations, such as for example hydrogen, formic gas consisting of hydrogen in nitrogen or ammonia NH₃.

Alternatively, the method may include a subsequent step for treatment at a temperature less than or equal to 500° C. in vacuo, in the case of vacuum molecular bonding, in order to reinforce molecular bonding and remove possible defects.

It is preferable, in order to obtain good quality of the bond, to provide a step for chemically cleaning the faces before the bonding, notably in the case when bonding is carried out under atmospheric pressure.

Thermal cleaning may be added or substituted for a chemical cleaning step in the case of molecular bonding achieved in vacuo. This thermal cleaning may for example be high temperature annealing under hydrogen of both faces before the bonding.

With the same purpose, it is preferable to provide a step for deoxidizing the faces between the cleaning step and the actual molecular bonding step.

At least one of the elements may be a block of bulk semiconducting material.

As a less costly alternative, at least one of the elements may be a film of a composite substrate formed by a stack in which the film is at the surface.

The composite substrate is advantageously a semiconductor-on-insulator substrate.

At least one of the elements may be doped in the bulk or may alternatively be doped at the surface.

Bonding might occur by introducing a flexure angle between both faces so as to cause a network of edge type dislocations at the bonding interface in addition to the network of screw type dislocations.

The semiconducting material of the elements may be silicon but also germanium, silicon-germanium.

In order to optimize efficiency, the rotational shift angle is adjusted in order to induce a network of screw type dislocations with a pitch as small as possible but non-zero.

The present invention also relates to a method for making a light-emitting diode wherein an electroluminescent PN junction is made by the method of the preceding claims and wherein on each element an electric contact is formed on a face opposite to the one which should be bonded.

When at least one of the elements is a film of a composite substrate, before forming its electric contact, an etching of the composite substrate may be achieved in order to expose the face which should bear the electric contact.

The present invention also relates to an electroluminescent PN junction, which includes two semiconducting crystalline elements doped with opposite type, these semiconducting elements having an indirect forbidden band and being assembled to each other by molecular bonding. It further includes at least one network of screw type dislocations at the bonding interface.

It may further include a network of edge type dislocations at the bonding interface, which makes it more performing.

The present invention also relates to an electroluminescent diode which includes a thereby characterized PN junction, each element being provided with an electric contact opposite to the bonding interface.

### SHORT DESCRIPTION OF THE DRAWINGS

The present invention will be better understood upon reading the description of given exemplary embodiments, purely as an indication and by no means as a limitation, with reference to the appended drawings wherein:

FIGS. 1A-1D show different steps for making an example of an electroluminescent PN junction and then an example of a light-emitting diode according to the invention;

FIGS. 2A-2C show another example of steps for making an electroluminescent PN junction and a light-emitting diode according to the invention;

FIGS. 3A-3D are graphs illustrating the intensity of the signal emitted by various diodes according to the invention or from the prior art versus the wavelength of the emitted signal.

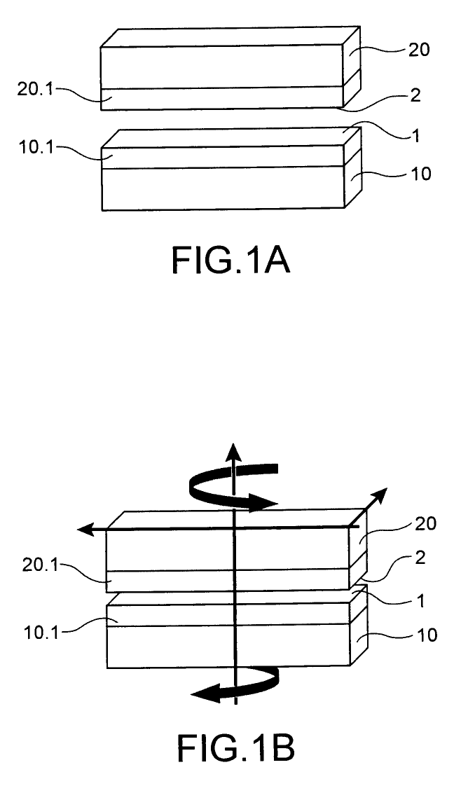

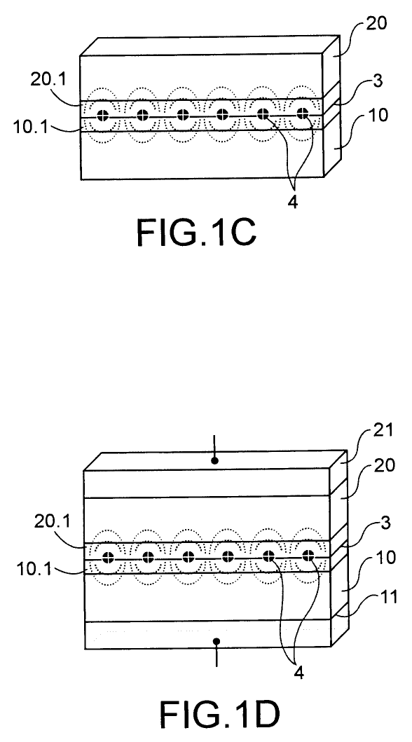

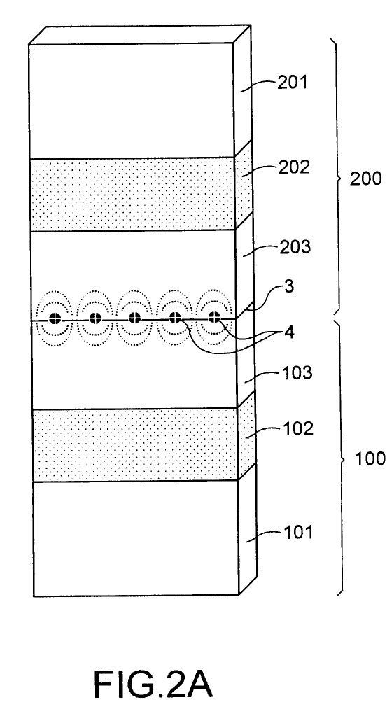

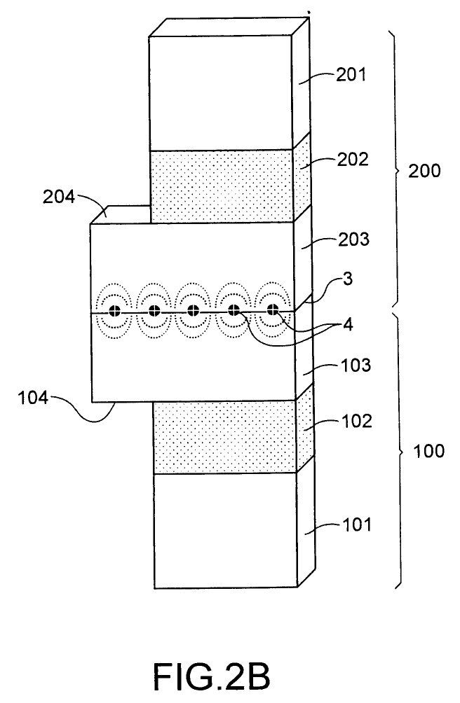

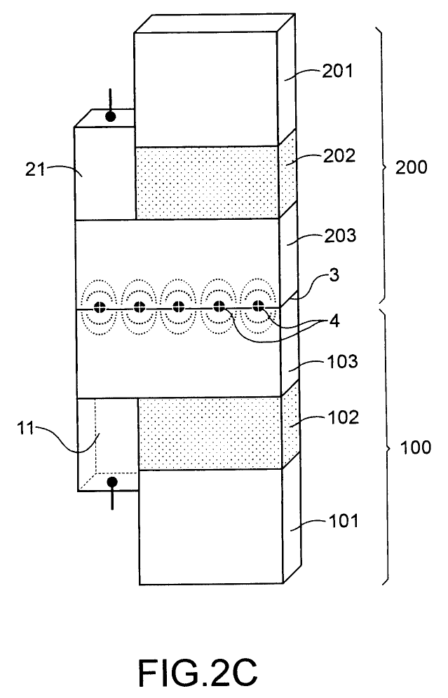

The various alternatives illustrated in FIGS. 1 and 2 should be understood as not being exclusive of each other.

Identical, similar or equivalent portions of the different figures described hereafter bear the same numerical references so as to facilitate passing from one figure to the other.

The different portions illustrated in the figures are not necessarily according to a uniform scale, so as to make the figures more legible.

### DETAILED DISCUSSION OF PARTICULAR EMBODIMENTS

A description will now be made of an exemplary method for making an electroluminescent PN junction object of the invention and then of a diode provided with this PN junction with reference to FIGS. 1A-1D.

One starts with two elements 10, 20 in a crystalline semiconducting material each having a bonding face 1, 2, as illustrated in FIG. 1A. This semiconducting material has an indirect forbidden band, this may for example be mono-crystalline silicon but other crystalline semiconducting materials may be used such as notably germanium, silicon germanium or any semiconductor with an indirect forbidden band. Both elements 10, 20 may be thick and bulk crystals of semiconducting material as illustrated in FIG. 1 or be films as illustrated in FIG. 2. By film, is meant a layer, the thickness of which is less than about 1 micrometer.

The material of one of the faces 1 has a doping type, for example an N type, and the material of the other face 2 has the opposite type, for example a P type.

Doping may be in the bulk, it may be achieved during the drawing of the crystal or else be at the surface, it might have been obtained for example by implanting a dopant. The dopant may for example be boron in the P-doped element 10 and phosphorus in the N-doped element 20. It is assumed that in the example of FIG. 1, the doping is at the surface and that it is in the bulk in the example of FIG. 2. The doped areas are referenced as 20.1 and 10.1 in FIG. 1A. The converse would be possible or one of the elements 1, 2 may have a doping in the bulk and the other a doping at the surface. The doping rate may be comprised between 10¹⁶ and a few 10²⁰ ions/cm³ knowing that the internal electric field of the PN junction will depend on the doping rate of each N or P area as in a conventional PN diode.

In order to make the PN junction, a face 1 in a crystalline semiconducting material of the first element 10 will be put into contact with a face 2 in a crystalline semiconducting material of the second element 20 so that the crystal lattices exhibited by said faces 1, 2 are shifted in rotation by a predetermined angle. This rotational shift angle is known as the twist angle. This twist angle is materialized in FIG. 1B by arrows. In this figure, the three crystalline axes of each of the elements 1, 2 are also visible.

This contacting is carried out with molecular bonding. Such an operation should be accomplished with sufficiently smooth surfaces and also as free as possible from contamination.

It is commonly recognized that any molecular bonding involves a cleaning step and then generally a step for deoxidizing the faces to be bonded, these steps being prior to the bonding applying molecular adhesion.

Both elements 10, 20 should be maintained sufficiently close to each other in order to allow intimate contact to be initiated. Attractive forces appear between the faces 1, 2 put into contact and cause molecular bonding.

This molecular bonding may be achieved at room temperature and at atmospheric pressure.

Therefore, prior cleaning of both faces 1, 2 is provided so as to allow this molecular adhesion. This cleaning known to one skilled in the art may notably when the bonding is carried out under atmospheric pressure, consist in chemical cleaning by immersion in one or several chemical baths for example based on hydrochloric acid HCl, nitric acid HNO₃; sulphuric acid H₂SO₄, hydrogen peroxide H₂O₂, ammonia NH₃, CARO mixture (H₂SO₄:H₂O), aqua regia, in RCA SC1 cleaning (NH₄OH:H₂O₂:H₂O) or RCA SC2 cleaning (H₂O₂:HCl:H₂O). This treatment may end with deoxidization treatment usually performed by hydrogenation of pendant bonds at the surface, by means of hydrofluoric acid HF as a liquid or vapour.

When silicon/silicon bonding is performed without an oxide layer at the surface, this is termed hydrophobic bonding. In the case of oxide/oxide bonding, this is termed hydrophilic bonding. In the method of the invention, this will preferably be hydrophobic bonding.

Molecular bonding may also be carried out in vacuo. A step for thermal cleaning and/or a step for chemical cleaning may be provided beforehand. Thermal cleaning may be annealing at a high temperature (typically above 1,100° C.) under hydrogen of the faces to be assembled, performed before bonding. The chemical cleaning may be similar to the one mentioned earlier. Molecular bonding in vacuo is carried out after prior deoxidization of both faces 1, 2 to be bonded either thermally in vacuo, or by any other deoxidization method. This technique is known to one skilled in the art.

Reinforcement of the bonding energies and energies of the network of ordered dislocations at the interface may be obtained by applying a heat treatment for example at a temperature above about 500° C. under a neutral atmosphere, for example in vacuo or under nitrogen, argon atmosphere, or of any other gas inert towards the materials to be bonded. Alternatively, this heat treatment may be carried out under a passivating atmosphere, for example under hydrogen, under hydrogen in nitrogen, under formic gas, under ammonia NH₃, or any other gas which does not prevent bonding or formation of the dislocation network. The duration of the heat treatment will depend on its temperature, it will be limited to a few hours in order not to let the dopants diffuse too much.

This annealing, so-called sealing annealing, has the purpose of reinforcing the molecular bonding and the formation of the dislocation network at the interface of the bonding, and of removing possible defects at the interface or allowing the formation of possible precipitates, for example of oxide, at the bonding interface or at the PN junction.

Thus, the majority of the bonds between both faces 1, 2 will be covalent bonds. This treatment aims at removing defects present at the bonding interface 3, such as bubbles.

If the molecular bonding was carried out in vacuo, instead of proceeding with a high temperature treatment, it is possible to proceed with a subsequent heat treatment at low temperature, less than about 500° C. for example and in vacuo.

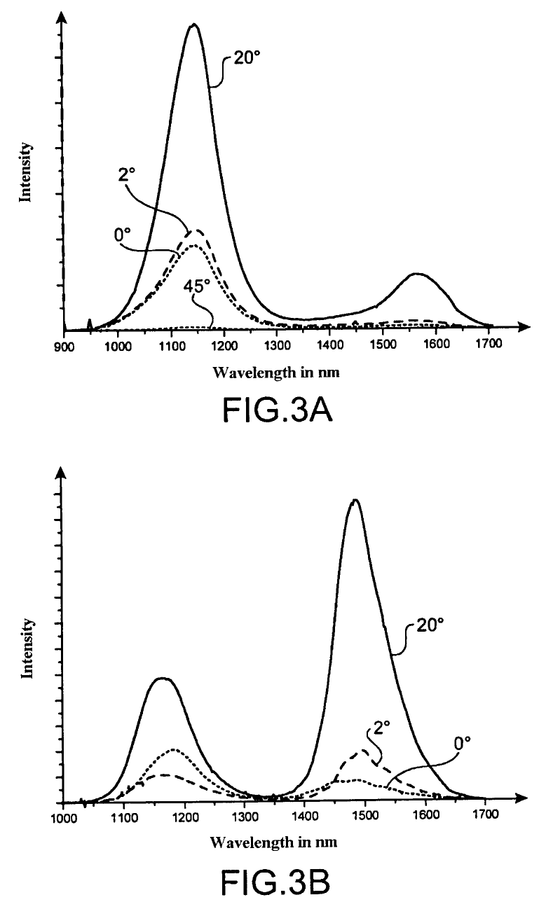

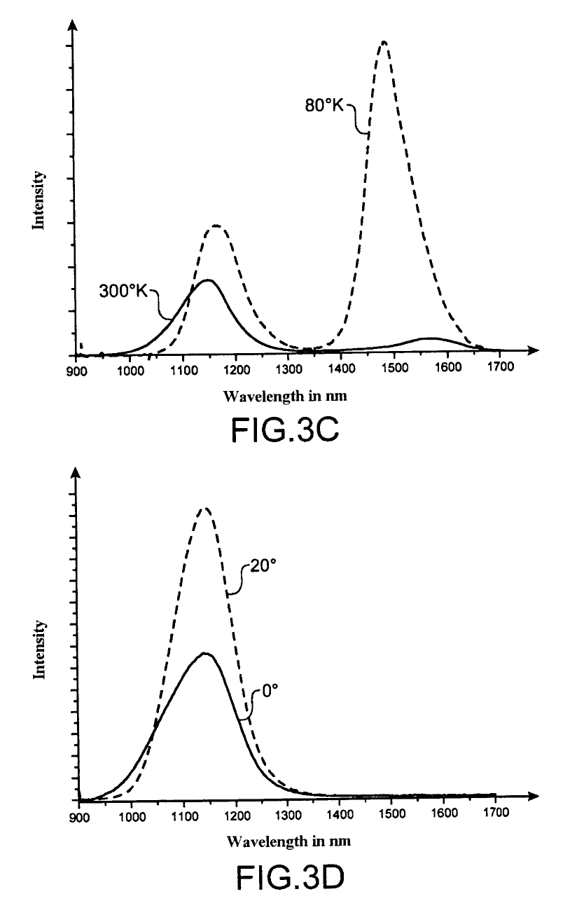

FIG. 1C shows the structure obtained after the bonding. Depending on the twist angle, a network of screw type dislocations 4 is induced at the bonding interface 3 and therefore at the junction PN. The latter has improved efficiency notably at room temperature and is capable of emitting at the wavelength corresponding to the forbidden bandwidth of silicon, but also at least at another wavelength, as this will subsequently be seen by examining the graphs of FIG. 3. In this example, the other wavelength is larger than the one corresponding to the forbidden band of silicon.

Indeed, it is known that the angular disorientation in rotation during the molecular bonding of two crystalline wafers induces, at the bonding interface, a square periodical network of screw type dislocations, the pitch of which depends on the twist angle. Reference may be made to article [4], the references of which are found at the end of the description.

With the screw type dislocation network, it is possible to locally modify the width of the forbidden band of the PN junction. First of all, it induces a localized field of spatial stresses with which the confinement of the electronic carriers may be increased at the PN junction, and their diffusion may be blocked, and the efficiency and internal quantum yield of the junction may notably be improved as compared with those of a junction without any dislocation.

With this bonding method, it is possible to control the pitch of the screw type dislocation network and therefore the dislocation density, since this pitch depends on the twist angle and this twist angle may be adjusted with great accuracy. It is thus possible to optimize the density of the dislocations, which conditions the emission and internal quantum yield of the obtained PN junction.

The article referenced as [4] describes a method for introducing a desired twist angle, with great accuracy, for example of the order of a hundredth of a degree, during the assembly. Both elements are taken from the same block of crystalline semiconducting material, the latter being provided with localization marks which may have the shape of graduated scales along a circular arc. Both taken elements will bear these localization marks. The desired twist angle may be obtained by aligning the localization marks by introducing a relative shift. Thus, a twist angle of 20° provides a screw dislocation pitch of about 1 nanometre.

If both elements do not stem from a same crystalline block, it is also possible to adjust the twist angle with great accuracy but at least one axis of the crystalline lattice of each of the elements has to be determined. This may be accomplished by means of X-rays for example.

In document [3], electroluminescence was only observed on samples exclusively having flexure disorientation, i.e. a tilt angle. Indeed, during the assembly by molecular bonding, it is generally sought not to introduce any twist angle so that the crystalline lattices coincide as much as possible, while being aware that the tilt angle is practically unavoidable except in the case of twin surfaces obtained by the smart-cut (registered trade mark) method.

Finally, the dislocations located at the bonding interface and therefore at the junction may also allow quantum wells to be formed because of emission at a lower energy than the gap, wells formed by the dislocations (emission around 1.5-1.6 micrometer of the luminescence lines of the dislocations, below the energy of the gap of silicon) or by the oxide precipitates which may form at the dislocations during the sealing annealing as taught in document [5], the references of which are given at the end of the description. These <<quantum wells>> locally modify the energy levels of the material used and allow emission of light at lower energy levels than those corresponding to the forbidden bandwidth of the crystalline material used. This means that the emitted light would have a different wavelength and in this case above the one corresponding to the forbidden bandwidth of the crystalline material used. The relationship which links energy and wavelength is:

Energy (in eV)×wavelength (in Å)≈12,410

During the assembling of any two elements, flexure disorientation occurs inevitably as this was seen earlier. This tilt angle as for it induces a second network of edge type dislocations at the interface 3, the pitch of which directly depends on this tilt angle, but also on the twist angle. It is assumed that this network of edge type dislocations is present in the example illustrated in FIG. 1, but it is superimposed with the screw type dislocation network, this is why it is not visible. The introduction of this second network of edge type dislocations can only reinforce electroluminescence of the junction notably at room temperature.

If both elements are taken from a same crystalline block, for example by fracture, and if they are assembled at the fracture, the tilt angle is zero.

The obtained PN junction may notably be used in integrated circuits or in diodes.

In order to obtain a light-emitting diode from the PN junction obtained previously, it is sufficient to make electric contacts 11, 21, each on one of the assembled elements 10, 20, opposite to the bonding interface 3. These electric contacts are referenced as 11 and 21 in FIG. 1D. These electric contacts 11, 21 may be made by spraying metal and possibly by thermal annealing. They may cover the totality of the face of the element 1, 2 which is opposite to the assembled one or may be delimited on this face. These electric contacts 11, 21 may be of the ohmic type or of the Schottky type. The electric contacts 11, 21 may for example be made on the basis of titanium, aluminium, nickel, gold, tungsten. The contacts will be of the ohmic or Schottky type depending on the type and doping rate of the semiconductor as well as on the nature of the metal used (the Fermi level of the metal/semiconductor). For example, a gold deposit on N type silicon or an aluminium deposit on P type silicon are generally ohmic after prior removal of the oxide at the surface of the silicon before depositing the metal. On the other hand, an aluminium deposit on N type doped silicon with a doping rate of less than 5.10¹⁹ ions/cm³ is of the Schottky type.

With these electric contacts 11, 21, it is possible to establish a current through the diode and inject electronic carriers into the PN junction with a dislocation network so that it emits light.

Another example of a PN junction according to the invention will now be considered with reference to FIG. 2A. Instead of both elements being thick bulk crystals, these may be two films 103, 203 each being part of a composite substrate 100, 200. It is assumed that both films 103, 203 are massively doped and no longer only at the surface. Such a composite substrate 100, 200 may be formed by a stack of several layers including the film at the surface. The stack may successively include a support 101, 201 generally in a semiconducting material, a dielectric material layer 102, 202 and a film 103, 203 in a crystalline semiconducting material. This may be a substrate of the semiconductor-on-insulator type and more specifically of the silicon-on-insulator type (SOI) or a germanium-on-insulator (GOI or GeOI) substrate. The assembly and the pre- and post-assembly treatments will be accomplished as described earlier in FIG. 1. The benefit from these SOI or other substrates lies in terms of applications for optics such as for example the making of photonic crystals, or for microelectronics.

In order to make the electric contacts 11, 21, a face opposite to the one which is assembled, of the films 103, 203, will preferably be partly exposed for each element. The exposed areas 104, 204 may be obtained by chemically etching the silicon, for example by means of KOH or TMAH solutions. This chemical etching may be completed by plasma etching techniques for the dielectric silicon oxide layer or with mixtures of hydrofluoric acid. This chemical etching is performed from the supports 101, 201 of the composite substrates 100, 200 through the dielectric layer 102, 202.

The electric contacts 11, 21 cover the exposed areas 104, 204. They may be made as described earlier for example by localized spraying.

Interest is now taken in graphs illustrating the intensity of the light emitted by the diodes according to the invention depending on the wavelength for different temperatures and at different twist angles, with reference to FIGS. 3A-3D.

In FIG. 3A, the measurements were conducted at 300° K (room temperature) with silicon PN junctions according to the invention. PN junctions having twist angles of 2°, 20°, 45° were tested. The tilt angle is not known and it may be zero but this is not very likely. A PN junction obtained by molecular bonding, having zero twist angle but having a given tilt angle and therefore part of the prior art, was also tested.

These twist angles for bondings with a twist angle of 0°, 2° and 20°, induced a periodical network of screw type dislocations with a pitch of 100 nm, 10 nm and 1 nm respectively. The bonding with a twist angle of 0° always has extremely low disorientation inducing a twist dislocation network with a pitch of the order of 100 nm, or even larger, comparable with the one generally observed for dislocations due to the tilt angle. It is realized that the smaller the pitch (but non zero), the stronger is the intensity of the signal. The curve corresponding to the twist angle of 20 degrees, has strongly marked peaks at the wavelength corresponding to the bandwidth of silicon (1,150 nm) but also around 1,550 nm. Electroluminescence efficiency is unquestionably improved with respect to the prior art. The sample from the prior art only emits a signal at the wavelength corresponding to the forbidden bandwidth of silicon, i.e. around 1,150 nm. In the absence of the dislocation network, i.e. in the case when the twist angle is 45°, the emitted signal is substantially zero.

In FIG. 3B, measurements were conducted at 80° K (low temperature) with silicon PN junctions according to the invention and conventional ones. They have twist angles of 2°, 20°, and a twist angle close to 0° or zero for the conventional junction. These angles induce a periodical network of dislocations of the screw type with a pitch of 10 nm for the twist angle of 2°, 1 nm for the twist angle of 20° and 100 nm for the zero twist angle, respectively. For the conventional PN junction, the tilt angle induces a network of edge type dislocations as well as a network of screw type dislocations with a minimum pitch of about a hundred manometers, due to the alignment imperfection of both elements. Indeed in practice, there generally remains a slight angular misalignment as it is difficult to perfectly align both crystalline lattices with an accuracy less than 0.010 as mentioned in document [4].

Here again, the smaller the pitch, the stronger is the intensity of the signal. The most intense peak is obtained in this case, in the range from 1,400 nm to 1,600 nm and more particularly around 1,500 nm. This wavelength is different and larger than the one which corresponds to the forbidden bandwidth of silicon. The other peak is found around 1,150 manometers.

FIG. 3C allows a comparison of the results obtained in FIGS. 3A and 3B for the junction according to the invention having the smallest pitch and therefore the strongest dislocation density. With the increase of the light intensity obtained around 1,500 nm at 80° K as compared with that obtained at 300° K, it is possible to infer that <<quantum wells>> are present in the tested PN junction at 80° K.

In FIG. 3D, at room temperature 300° K, the intensity of the signal of a PN junction of the invention was compared with that delivered by a convention PN junction. Both junctions are silicon junctions. The PN junction of the invention, obtained by bonding, has a twist angle of 20° and a power of 0.156 W has been injected into it. The conventional PN junction, also obtained by bonding, has a zero twist angle. A power of 2.2 W was injected into it. Both elements of these junctions were treated with liquid hydrofluoric acid before assembly. Comparison is performed at the wavelength corresponding to the forbidden bandwidth of silicon. Taking into account the injected powers, it may be inferred that the PN junction according to the invention is forty times more efficient than the conventional one.

Although several embodiments of the present invention have been illustrated and described in detail, it will be understood that various changes and modifications may be provided without departing from the scope of the invention. Notably, it is possible that one of the elements is a bulk semiconducting material and that the other element is a film.

### QUOTED DOCUMENTS

[1] “An efficient room-temperature silicon-based light-emitting diode” Wai Lek Ng et al., Nature, Vol. 410, 8 Mar. 2001, pages 192-194.
[2] “Room-temperature silicon light-emitting diodes based on dislocation luminescence” V. Kveder et al., Applied Physics Letter, Volume 84, Number 12, 22 Mar. 2004, pages 2106-2108.
[3] “Electroluminescence from silicon P-N junctions prepared by wafer bonding”, Einar Ô, Sveinbjörnsson et al. Electrochemical Society Proceedings, Sep. 1, 2002, Vol. 97-36, pages 264-271.
[4] “Accurate control of the misorientation angles in direct wafer bonding” Frank Fournel et al. Applied Physics Letters, Volume 80, Number 5, 4 Feb. 2002, pages 793-795.
[5] “Optical properties of oxygen precipitates and dislocations in silicon” S. Binetti et al. Journal of Applied Physics, Volume 92, Number 5, 1 Sep. 2002, pages 2437-2445.

1-19. (canceled)

20. A method for making an electroluminescent PN junction comprising:
molecular bonding a face in a crystalline semiconducting material doped with a first type of a first element with a face in a crystalline semiconducting material doped with a second type opposite to the first type of a second element at a bonding interface, the semiconducting material having an indirect forbidden band,
wherein the bonding is carried out by shifting in rotation by a predetermined angle crystalline lattices shown by the faces, so as to at least cause formation of a network of dislocations of screw type at the bonding interface.

21. The method according to claim 20, further comprising a subsequent thermal annealing, under a neutral or passivating atmosphere, capable of reinforcing the molecular bonding and removing defects at the bonding interface.

22. The method according to claim 20, wherein the bonding is carried out in vacuo, the method further comprising a subsequent treatment at a temperature less than or equal to 500° C. in vacuo, capable of reinforcing molecular bonding and removing defects.

23. The method according to claim 20, wherein the molecular bonding is carried out at atmospheric pressure, the method further comprising chemically cleaning the faces, prior to the molecular bonding.

24. The method according to claim 20, wherein the molecular bonding is accomplished in vacuo, the method further comprising chemically and/or thermally cleaning the faces in vacuo, prior to the molecular bonding.

25. The method according to claim 23, further comprising deoxidizing the faces between the cleaning and the bonding.

26. The method according to claim 20, wherein at least one of the elements is a block of massive semiconducting material.

27. The method according to claim 20, wherein at least one of the elements is a film of a composite substrate formed by a stack in which the film is at the surface.

28. The method according to claim 27, wherein the composite substrate is a semiconductor-on-insulator substrate.

29. The method according to claim 20, wherein at least one of the elements is doped in bulk.

30. The method according to claim 20, wherein at least one of the elements is doped at the surface.

31. The method according to claim 20, wherein bonding is performed by introducing a flexure angle between both faces so as to cause a network of edge type dislocations at the bonding interface in addition to the network of screw type dislocations.

32. The method according to claim 20, wherein the semiconducting material is silicon, germanium, silicon-germanium.

33. The method according to claim 20, wherein a rotational shift angle is adjusted to induce a network of screw type dislocations with a pitch as small as possible but non-zero.

34. A method for making a light-emitting diode, wherein an electroluminescent PN junction is made by the method according to claim 20, and on each element an electric contact is formed on a face opposite to the face to be bonded.

35. The method according to claim 34, wherein when at least one of the elements is a film of a composite substrate, etching of the composite substrate is performed before forming its electric contact, to expose the face to bear the electric contact.

36. An electroluminescent PN junction, comprising:
two doped semiconducting crystalline elements of opposite types, assembled to each other by molecular bonding, the semiconductor having an indirect forbidden band; and
at least one network of screw type dislocations at the bonding interface.

37. The PN junction according to claim 36, further comprising a network of edge type dislocations at the bonding interface.

38. A light-emitting diode, comprising a PN junction according to claim 36, each element including an electric contact, opposite to the bonding interface.
